(19) United States
(12) Patent Application Publication
(10) Pub. No.: US 2022/0229116 A1
(43) Pub. Date: Jul. 21, 2022

(54) Method and Device for Determining the Degradation of a Battery Module or Battery Cell

(71) Applicant: Siemens Aktiengesellschaft, Muenchen (DE)

(72) Inventors: Kristian FENECH, Budapest (HU); Gergely György Balazs, Budapest (HU); Hanna Fischer, Budapest (HU)

(21) Appl. No.: 17/614,051

(22) PCT Filed: May 19, 2020
(86) PCT No.: PCT/EP2020/063965

§ 371 Date: Nov. 24, 2021

(30) Foreign Application Priority Data
May 27, 2019 (EP) 19176730

(51) Int. Cl. G01R 31/367; G01R 31/392; H01M 10/48

(52) U.S. Cl. CPC G01R 31/367; H01M 10/486; G01R 31/392

(57) ABSTRACT

Method for determining the degradation of a battery module or a battery cell that each deliver energy to an electric load, wherein a) a battery parameter set comprising an actual temperature of the battery module is captured, b) a load parameter set is captured, c) an environmental parameter set is captured, d) a machine learning model is set up and trained with the battery parameter set, the load parameter set and the environmental parameter set, e) a predicted temperature and a standard deviation thereof is calculated using the machine learning model, and the degradation of the battery module is determined using a predicted temperature, the standard deviation and the actual temperature, where a change over the time of the probability of measuring the actual module or cell temperature, which is normal distributed, is an indicator for the degradation of the battery module or battery cell.

### CROSS-REFERENCE TO RELATED APPLICATIONS

This is a U.S. national stage of application No. PCT/EP2020/063965 filed 19 May 2020. Priority is claimed on European Application No. 19176730.0 filed 27 May 2019, the content of which is incorporated herein by reference in its entirety.

### BACKGROUND OF THE INVENTION

### 1. Field of the Invention

The invention relates to a method and a device for determining the degradation of a battery module or battery cell.

### 2. Description of the Related Art

The problem of battery health management is now becoming a more significant issue as electric mobility and large-scale battery systems for grid level energy storage become increasingly prevalent. The nature of these large systems typically renders measurement of current levels of health difficult and costly.

The health of a battery indicates in-depth details about battery aging effects such as the remaining absolute usage time, where the aging effects are caused, for instance, by the number of charging cycles, the physical battery age, temperatures at operation and charging of the battery or charging and discharging (i.e., energy delivery) profiles.

In the prior art, health degradation in batteries is typically measured at the individual cell level in a laboratory environment and can be determined by a measurement of the open circuit voltage (OCV) of a battery cell, incremental capacity analysis (ICA) or impedance spectroscopy methods to form inputs to Fuzzy logic systems or predetermined look-up tables.

The publication US 2016/349330 A1 discloses a method for predicting remaining battery life by machine learning, which is based on rudimentary temperature and voltage prediction, including environmental conditions like exposed humidity levels over time. However, the machine learning model still lacks accuracy and reliability of the prediction for certain applications.

### SUMMARY OF THE INVENTION

In view of the foregoing, it is an object of the invention to provide an in-situ measurement method that solves the foregoing problem by estimating the level of degradation in a battery module or battery cell health.

This and other objects and advantages are achieved in accordance with the invention by a method for determining the degradation of a battery module or a battery cell, where the battery module or battery cell delivers energy to an electric load. The method includes:
a) capturing a battery parameter set comprising an actual temperature of the battery module or battery cell,
b) Capturing a load parameter set of the load,
c) Capturing an environmental parameter set of the environment of the battery module or battery cell,
d) setting up and training a machine learning model with the battery parameter set, the load parameter set and the environmental parameter set,
e) calculating a predicted temperature and a standard deviation thereof using the machine learning model, and
f) determining the degradation of the battery module using the predicted temperature, the standard deviation and the actual temperature, where a change over the time of the probability of measuring the actual module or cell temperature, which is normal distributed, is an indicator for the degradation of the battery module or battery cell.

The load parameter set can be any set of parameters that accurately describe the load that is being powered by the battery module.

The invention has its merit in providing the capability to use in-situ-measurements for the determination of the degradation of a battery module, which easily can be made without manual interaction with the battery module or cell and which can be performed outside a laboratory testing environment. Thus, reductions in cost and downtime of a respective system can be obtained.

Such a technique could be applied to systems in which temperature can be used as a substitute for the exact knowledge of the level of degradation in a system.

The notion of health of a battery module or a battery cell can be derived by a localized temperature within a battery pack as a function T(x,t), where the input x is a vector comprised of the dedicated measurements and t is the time.

The standard deviation of the temperature and the battery parameter set respectively relates to the standard deviation of the battery module or battery cell temperature, captured over time at controlled operational conditions and stored within a machine learning model of the battery module or cell. It is clear that these data must be considered within the machine learning model at model setup.

In a further embodiment of the invention, the battery parameter set, the load parameter set and the environmental parameter set are captured in-situ, i.e., during energy delivery (discharging) of the battery module or battery cell.

The determination of the degradation of a battery module is performed by simple in-situ-measurements and, thus, the lifetime of the battery module can be determined efficiently.

In a further embodiment of the invention, the battery parameter set comprises at least one parameter related to at least one voltage and/or at least one current of the battery module or at least one cell of the battery module.

A voltage or rather a current of the battery module or cell can accurately describe the load that is being powered by the battery module and moreover being captured easily and automatically by respective sensors.

In a further embodiment of the invention, the electric load comprises an inverter, and the load parameter set comprises a parameter related to the power consumption of the inverter.

Thus, AC loads can also be applied, and the conversion efficiency of the inverter is additionally included to obtain a high precision at the determination of the degradation.

In a further embodiment of the invention, the electric load comprises an electric motor, and the load parameter set comprises at least one parameter related to at least one current, at least one voltage, a rotational speed, a magnetic flux and/or a motor torque of the electric motor.

The currents can be, for instance, an AC current (RMS), a d-axis current, a q-axis current and/or a DC current of the motor.

This load parameter set provides an accurate feature set in which the battery temperature may be estimated for a battery that is in use in an electric vehicle.

The d/q transformation, also referred to as dq, dq0 and Park transformation, serves to convert three-phase quantities, such as in a three-phase machine with the axes U, V, W, into a two-axis coordinate system with the axes d and q.

It is part of the mathematical basics of vector control of three-phase machines and describes one of several possible space vector representations. In contrast to the related Clarke transformation, the d/q coordinate system rotates in the stationary case with the rotor and the value pair d/q then represents time-constant quantities.

A three-phase system is described in the complex plane by three coordinates U, V, W, each offset by an angle of 120°. The three coordinates U, V, W correspond to the three coils of the stationary stator of a rotary field machine, whereby by definition the axis U coincides with the real axis, as shown in the first figure of the fixed αβ-coordinate system of the Clarke transformation. Currents flowing through these coils are always 0 in total for a symmetrical three-phase system.

In the d/q transformation, the coordinate system with the mutually perpendicular axes d and q with the angular frequency is co-rotated with the rotor. Thus, the rotating field at constant speed in the form of two temporally constant quantities d and q can be described. The value d represents the magnetic flux density of the magnetic excitation in the rotor, and q is an expression of the torque generated by the rotor. Time changes such as the speed or torque fluctuations result in changes in time of d or q. The advantage of the transformation is that induction machines can be controlled with a PI controller just as easily as DC machines.

In order to rotate the d/q coordinate system with the correct angular velocity and phase angle with the rotor, it is necessary to know the exact position in the form of the angle of the rotor. This information, which is essential for the transformation, can be obtained with sensors additionally mounted on the machine, such as Hall sensors or optical sensors, or by feedback such as the evaluation of the electromotive force (EMF) on the stator winding.

The transformation is not limited to the electric currents but can be applied analogously for all other electrical quantities such as the occurring electrical voltages or the magnetic flux density.

In a further embodiment of the invention, the environmental parameter set comprises at least one parameter related to an ambient air temperature in proximity of the battery module. Consequently, the degradation can be calculated in an easy way.

In a further embodiment of the invention, the machine learning model is a random forest regression tree.

A temperature T(x,t) can be determined through a machine learning method such as a Random Forest Regression tree model, which is built using historic data from the battery usage in a known nominal state with low amounts of degradation as compared to an unused pack.

Basically, statistical data, such as a mean value or a standard deviation or a statistical distribution, can be obtained by using historic data, included for instance in the machine learning model, e.g., from the battery usage in the known nominal state with low amounts of degradation compared to an unused pack, which represent an example of controlled conditions for battery module or cell operation. As a result, the degradation can be calculated in an easy and reliable way.

In a further embodiment of the invention, a change over the time of a probability of measuring the actual module or cell temperature T_{act}, which is normal distributed, is an indicator for the degradation of the battery module or battery cell.

In other words, the probability of measuring an actual temperature is the probability for obtaining a respective measurement value subsequently.

Pr(X=T_{act}) is the probability of measuring an module or cell temperature T_{act} with a given normal distribution X˜ [symbol] (T_{pred},σ_{T}) where X is a normal distributed random variable with the mean T_{pred} and the standard deviation σ_{T}.

The change over time of the probability Pr(X=T_{act}) is an indicator for the degradation of the battery module or cell, because X is a normal distribution of the predicted temperature T_{pred}, derived from observing the actual temperature T_{act}.

Degradation is most commonly associated with increased resistance and therefore increased joule heating. Thus, the degradation can be derived from the actual module or cell temperature.

If the probability of observing T_{act} is very low, then the term Pr(X=T_{act}) will go to zero or some very small positive value and the degradation will only increase by a large amount.

$$( 1 - P r ( X = {T}_{a c t} ) ) \text{∼} 1$$

Further, if the probability of observing such a temperature on a non-degraded battery is very high, the following relationship can be derived:

$$( 1 - P r ( X = {T}_{a c t} ) ) \text{∼} 0$$

It is also an object of the invention to provide a battery monitoring device having a calculation unit and a memory for determining the degradation of a connected battery module or battery cell, where the battery module or battery cell is configured to deliver energy to an electric load, and the battery monitoring device is configured to implement the method in accordance with the disclosed embodiments of the invention.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The invention will be explained in more detail with reference to an embodiment shown in the accompanying drawings, in which:

FIG. 1 is a schematic illustration of an embodiment of the device in accordance with the invention;

FIG. 2 is a schematic illustration of an embodiment of the method in accordance with the invention,

FIG. 3 a flowchart of the steps of the method of FIG. 2.

### DETAILED DESCRIPTION OF THE EXEMPLARY EMBODIMENTS

It is clear, that further not shown parts are necessary for the operation of a device, e.g., sensor devices, driver circuitries, electric connection to a power supply and electronic control components but also mechanical parts, like housings or fastening materials. For the sake of better understanding these parts are not illustrated and described.

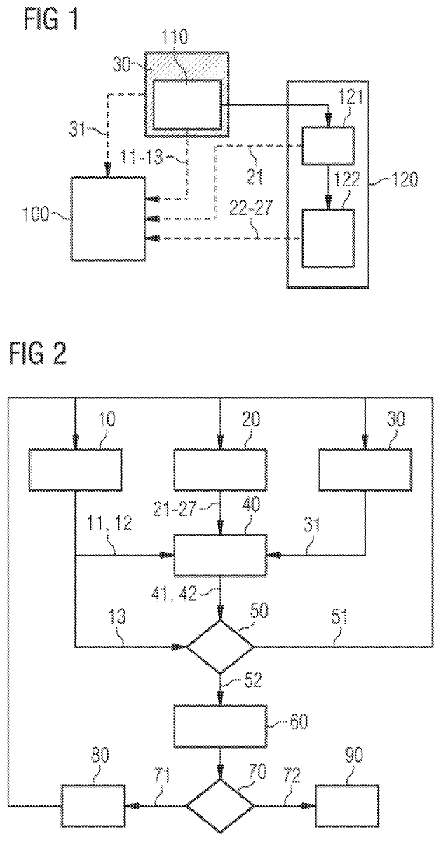

FIG. 1 shows a schematic illustration of an embodiment of a device in accordance with the invention with a battery monitoring device 100 with a calculation unit and a memory for determining the degradation of a battery module 110 or a battery cell.

The battery module 110 is configured to deliver energy to an electric load 120.

The electric load comprises an inverter 121 and an electric motor 122, where the inverter 121 controls and supplies the motor 122.

The battery monitoring device 100 is configured to capture a battery parameter set 10 including a battery module/cell temperature 11, a battery module/cell voltage 12 and a battery module/cell current 13 from the battery module 110 or battery cell.

Moreover, the device 100 is configured to capture a load parameter set 20 from the inverter 121 including an inverter power consumption 21.

Further, the device 100 is configured to capture the load parameter set 20 from the motor 122 including an AC current 22 (RMS), a d-axis current 23, a q-axis current 24, a DC current 25, a rotational speed 26 and a motor torque 27.

The device 100 is also configured to capture an environmental parameter set 30 in proximity of the battery module 110/cell including an ambient air temperature 31.

Capturing means can be adequate sensors.

A battery monitor device 100 is configured to carry out the method according to the invention, which is explained in the following.

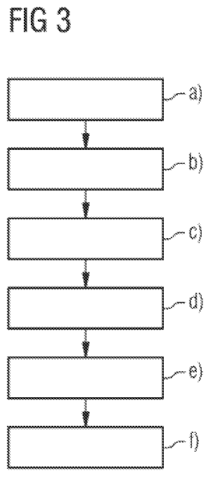

FIG. 2 and FIG. 3 show a schematic illustration of an embodiment of the method in accordance with the invention.

The method comprises:
a) capturing a battery parameter set 10 comprising an actual temperature 11 of the battery module 110,
b) capturing a load parameter set 20 of the load 120,
c) capturing an environmental parameter set 30 of the environment of the battery module 110,
d) setting up and training a machine learning model 40 with the battery parameter set 10, the load parameter set 20 and the environmental parameter set 30, including historic battery parameter sets captured at controlled operational conditions,
e) calculating a predicted temperature 41 and a standard deviation 42 thereof using the machine learning model 40,
f) determining the degradation of a battery module 110 using predicted temperature 41, the standard deviation 42 and the actual temperature 11, where a change over the time of the probability of measuring the actual module or cell temperature 11, which is normal distributed, is an indicator for the degradation of the battery module or battery cell.

The machine learning model 40 is a random forest regression tree.

A change over the time of a probability of measuring the actual module temperature 11 (i.e., T_{act}), which is normally distributed, is an indicator for the degradation of the battery module 110.

The actual module temperature 11 (i.e., T_{act}) can be captured directly at the battery module 110 by one or more temperature sensors attached to specific battery cells of the battery module 110.

Pr(X=T_{act}) is the probability of measuring a module or cell temperature T_{act} with a given normal distribution X˜ [symbol] (T_{pred},σ_{T}), where X is a normal distributed random variable with the mean 41 (i.e., T_{pred}) and the standard deviation 42 (i.e., σ_{T}).

The change over time of the probability Pr(X=T_{act}) is an indicator for the degradation of the battery module 110, because X is a normal distribution of the predicted temperature T_{pred}, derived from observing the actual temperature T_{act}.

Degradation is most commonly associated with increased resistance and therefore increased joule heating. Thus, the degradation can be derived from the actual module or cell temperature.

If the probability of observing T_{act} is low, then the term Pr(X=T_{act}) will go to zero or some very small positive value and the degradation will only increase by a large amount.

$$( 1 - P r ( X = {T}_{a c t} ) ) \text{∼} 1$$

Further, if the probability of observing such a temperature on a non-degraded battery is very high, then the following relationship can be derived:

$$( 1 - P r ( X = {T}_{a c t} ) ) \text{∼} 0$$

A machine learning algorithm can be built based on the features of the load parameter set to model the normal behavior (temperature) of the battery cells during operation.

With the model, the temperature 41 (T_{pred}) at any given time during the operation of the battery can be estimated.

Based on the historic data acquired from the battery, the standard deviation interval 42 (i.e., σ_{T}) can be applied to the estimated temperature 41 (i.e., T_{pred}), which defines the confidence bound on the predicted value.

At a range approval step 50, whether the actual temperature T_{act} is within the interval T_{pred}±σ_{T} is calculated.

If the approval 50 has as a result 51 “YES”, then the method will be repeated, and the battery monitoring is continued.

If the approval 50 has as a result 52 “NO”, then a degradation parameter 60 is calculated.

The degradation can be represented as D_{N} at the N^{th} measurement of the degradation.

If subsequently remeasured values of the temperature are within the interval, the degradation is considered as non-significant.

If subsequently remeasured values of the temperature are outside the interval, then the level of degradation is increased and considered as significant.

In an exemplary implementation,

$${D}_{N} = {D}_{N - 1} + λ \cdot ( 1 - Pr ( X = {T}_{a c t} ) )$$

where
Pr(X=T_{act}) is the probability of measuring a temperature with a given X˜ [symbol] (T_{pred},σ_{T}),
D₀=0 is the baseline degradation in health at the time of production, and
λ≥1 is a configurable parameter that is used to set how conservative the algorithm is in terms of adding degradation to the system.

Increases in D over time, i.e., the change over the time of the probability of measuring the actual module or cell temperature 11, can be tracked until the degradation exceeds a predefined threshold,

$$\vert {D}_{N} \vert > {D}_{T h reshold}$$

where
D_{Threshold} is a prescribed cutoff value, in which the health of the battery has degraded beyond a tolerated safety margin.

Thus, at a threshold approval step 70 a calculation of whether the degradation parameter is below a predefined threshold is performed.

If the approval 70 has as a result 71 “YES”, then a step of storing degradation parameter 80 is performed. Stored degradation parameters can be used at the setup and training of the machine learning model.

If the approval 70 has as a result 72 “NO”, then a warning signal 90 to an operator can be made, since the degradation of the battery module 110 has reached a critical stage.

Appropriate action steps, for instance raising an alarm based on the usage scenario and relevant regulations can be further made.

FIG. 3 shows an exemplary sequence of the steps of the method, but alternative sequences will also work, like parallel steps a) to c).

Thus, while there have been shown, described and pointed out fundamental novel features of the invention as applied to a preferred embodiment thereof, it will be understood that various omissions and substitutions and changes in the form and details of the methods described and the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1.-8. (canceled)

9. A method for determining degradation of a battery module or a battery cell which each deliver energy to an electric load, the method comprising:
a) capturing a battery parameter set comprising an actual temperature of the battery module or battery cell;
b) capturing a load parameter set of the load;
c) capturing an environmental parameter set of the environment of the battery module or battery cell;
d) setting up and training a machine learning model with the captured battery parameter set, the captured load parameter set and the captured environmental parameter set;
e) calculating a predicted temperature and a standard deviation thereof utilizing the machine learning model;
f) determining the degradation of the battery module or battery cell utilizing the calculated predicted temperature, the calculated standard deviation and the actual temperature, a change over time of a probability of measuring the actual module or cell temperature, which is normal distributed, being an indicator for the degradation of the battery module or battery cell.

10. The method according claim 9, wherein the battery parameter set, the load parameter set and the environmental parameter set are captured during energy delivery of the battery module or battery cell.

11. The method according to claim 9, wherein the battery parameter set comprises at least one parameter related to at least one voltage and/or at least one current of the battery module or at least one cell of the battery module.

12. The method according to claim 9, wherein the electric load comprises an inverter, and the load parameter set comprises a parameter related to power consumption of the inverter.

13. The method according to claim 9, wherein the electric load comprises an electric motor, and the load parameter set comprises at least one of at least one parameter related to at least one current, at least one voltage, a rotational speed, a magnetic flux and a motor torque of the electric motor.

14. The method according to claim 9, wherein the environmental parameter set comprises at least one parameter related to an ambient air temperature proximal to the battery module.

15. The method according to claim 9, wherein the machine learning model is a random forest regression tree.

16. A battery monitoring device comprising:
a calculation unit and a memory for determining degradation of a connected battery module or battery cell,
wherein the battery module or battery cell is configured to deliver energy to an electric load; and
wherein the battery monitor device is configured to:
a) capture a battery parameter set comprising an actual temperature of the battery module or battery cell;
b) capture a load parameter set of the load;
c) capture an environmental parameter set of the environment of the battery module or battery cell;
d) set up and train a machine learning model with the captured battery parameter set, the captured load parameter set and the captured environmental parameter set;
e) calculate a predicted temperature and a standard deviation thereof utilizing the machine learning model;
f) determine the degradation of the battery module or battery cell utilizing the calculated predicted temperature, the calculated standard deviation and the actual temperature, a change over time of a probability of measuring the actual module or cell temperature, which is normal distributed, being an indicator for the degradation of the battery module or battery cell.
